(19) United States
(12) Patent Application Publication
(10) Pub. No.: US 2026/0003014 A1
(43) Pub. Date: Jan. 1, 2026

(54) VEHICLE CHARGING SYSTEM FOR AN ELECTRIC VEHICLE HAVING ARC DETECTION

(71) Applicant: TE Connectivity Solutions GmbH, Schaffhausen (CH)

(72) Inventors: Nathan Philip Myer, Middletown, PA (US); David Bruce Sarraf, Middletown, PA (US); Robin Wesson, Middletown, PA (US); Paul Angell, Middletown, PA (US)

(21) Appl. No.: 18/976,560

(22) Filed: Dec. 11, 2024

Related U.S. Application Data
(60) Provisional application No. 63/665,335, filed on Jun. 28, 2024.

(51) Int. Cl. G01R 31/58; B60L 53/16; B60L 53/62; G01R 31/40; H02J 7/00

(52) U.S. Cl. CPC G01R 31/58; B60L 53/16; G01R 31/40; H02J 7/0042; B60L 53/62

(57) ABSTRACT

A vehicle charging system for an electric vehicle includes charging terminals held in a housing and connected to corresponding power conductors to form power transmission lines. The vehicle charging system includes a charging controller for controlling vehicle charging along the power transmission lines. The vehicle charging system includes an arc sensor assembly coupled to the charging controller. The arc sensor assembly includes a diversity antenna for detecting arc signatures along the power transmission lines from an arc event. The diversity antenna transmits an arc output signal to the charging controller based on detection of the arc signature.

### CROSS REFERENCE TO RELATED APPLICATIONS

This application claims benefit to U.S. Application No. 63/665,335, filed 28 Jun. 2024, the subject matter of which is herein incorporated by reference in its entirety.

### BACKGROUND OF THE INVENTION

The subject matter herein relates generally to vehicle charging systems.

Electric vehicles (EV) and hybrid electric vehicles (HEV) include battery systems for operating the vehicles. The battery systems are charged by a vehicle charging system. For example, a charging connector, which is coupled to a power source, is connected to a charging inlet assembly of the vehicle to charge the battery. Known vehicle charging systems are not without disadvantages. For instance, the temperature of the terminals increase during charging, which may lead to damage to the charging components. In some instances, arcing may occur between the charging components, which can damage the charging connector and the charging inlet assembly.

A need remains for an arc detection method for a vehicle charging system of an electric vehicle.

### BRIEF DESCRIPTION OF THE INVENTION

In one embodiment, a vehicle charging system for an electric vehicle is provided and includes a housing having a mating end for mating with a charging component for the electric vehicle. The housing includes an internal cavity. The vehicle charging system includes charging terminals held by the housing in the internal cavity. Each charging terminal includes a mating end for mating with the charging component. The charging terminals are connected to corresponding power conductors to form power transmission lines. The vehicle charging system includes a charging controller for controlling vehicle charging along the power transmission lines. The vehicle charging system includes an arc sensor assembly coupled to the charging controller. The arc sensor assembly includes a diversity antenna for detecting arc signatures along the power transmission lines from an arc event. The diversity antenna transmits an arc output signal to the charging controller based on detection of the arc signature.

In another embodiment, a vehicle charging system for an electric vehicle is provided and includes a housing having a mating end for mating with a charging component for the electric vehicle. The housing includes an internal cavity. The vehicle charging system includes charging terminals held by the housing in the internal cavity. Each charging terminal includes a mating end for mating with the charging component. The charging terminals are connected to corresponding power conductors to form power transmission lines. The vehicle charging system includes a charging controller for controlling vehicle charging along the power transmission lines. The vehicle charging system includes an arc sensor assembly coupled to the charging controller. The arc sensor assembly includes a diversity antenna for detecting arc signatures along the power transmission lines from an arc event. The diversity antenna includes a primary diversity antenna element sensing first signals and a secondary diversity antenna element sensing second signals. The arc sensor assembly includes a receiver receiving signals from at least one of the primary diversity antenna element and the secondary diversity antenna element. The arc sensor assembly includes a noise blanker operably coupled to the receiver to control the signals received by the receiver. The arc sensor assembly transmits an arc output signal to the charging controller based on the signals received by the receiver.

In a further embodiment, a charging inlet assembly for an electric vehicle is provided and includes a housing extending between a front and a rear. The housing has a chamber at the rear. The housing has a power connector at the front for receiving a charging connector. The power connector includes terminal channels between the front and the rear. The charging inlet assembly includes charging terminals received in the corresponding terminal channels. Each of the charging terminals includes a mating pin and a terminating end opposite the mating pin. The mating pin is positioned in the corresponding terminal channel for mating with the charging connector. The terminating end is positioned in the chamber at the rear of the housing and being connected to a power conductor to form a power transmission line. The charging inlet assembly includes a charging controller for controlling vehicle charging along the power transmission lines during a charging operation. The charging inlet assembly includes an arc sensor assembly coupled to the charging controller. The arc sensor assembly includes a diversity antenna for detecting arc signatures along the power transmission lines from an arc event. The diversity antenna transmits an arc output signal to the charging controller based on detection of the arc signature.

### BRIEF DESCRIPTION OF THE DRAWINGS

FIG. 1 is a schematic view of a vehicle charging system in accordance with an exemplary embodiment.

FIG. 2 is a front perspective view of a charging component in accordance with an exemplary embodiment.

FIG. 3 is a rear perspective view of the charging component in accordance with an exemplary embodiment.

FIG. 4 is a perspective view of the charging controller in accordance with an exemplary embodiment.

FIG. 5 is a cross-sectional view of the charging component in accordance with an exemplary embodiment showing a second charging component coupled to the charging component.

FIG. 6 is a cross sectional view of the charging component in accordance with an exemplary embodiment showing the second charging component coupled to the charging component.

FIG. 7 is a schematic view of the vehicle charging system for the vehicle in accordance with an exemplary embodiment.

### DETAILED DESCRIPTION OF THE INVENTION

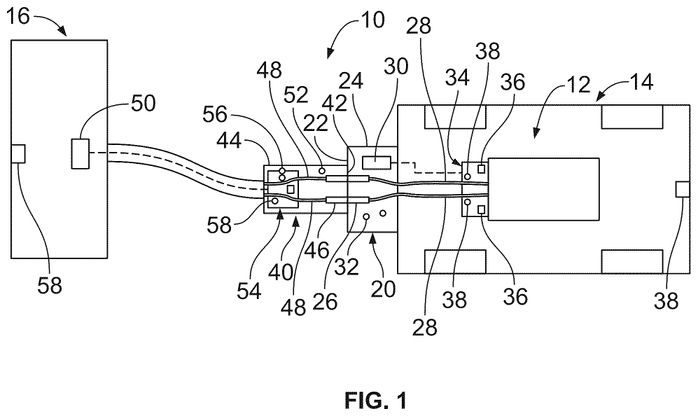

FIG. 1 is a schematic view of a vehicle charging system 10 in accordance with an exemplary embodiment. The vehicle charging system 10 is used for charging a battery system 12 of a vehicle 14, such as an electric vehicle or a hybrid electric vehicle. The vehicle charging system 10 includes a first charging component 20 and a second charging component 40. The first and second charging components 20, 40 are coupled together to charge the battery system 12 of the vehicle 14. In an exemplary embodiment, the first charging component 20 is coupled to the vehicle 14 and the second charging component 40 is coupled to a power supply 16 used for charging the battery system 12 of the vehicle 14. For example, the first charging component 20 may be a charging inlet assembly 22 mounted to the vehicle 14 and the second charging component 40 may be a charging connector 42 (for example, charging plug) which may be provided at a charging station or coupled to the building wiring of the home or building where the vehicle 14 is parked.

The first charging component 20 includes a housing 24 holding a plurality of charging terminals 26 and power conductors 28 coupled to the charging terminals 26. The charging terminals 26 may be DC charging terminals and/or AC charging terminals. The power conductors 28 may be power cables, busbars, or other types of conductors.

The first charging component 20 includes a charging controller 30, which may be used to control vehicle charging. For example, the charging controller 30 may control power supply along the charging terminals 26. The charging controller 30 may communicate with the second charging component 40, such as to control the second charging component 40. For example, the charging controller 30 may cause the second charging component 40 to turn on the power supply, turn off the power supply, increase power supply, and/or decrease power supply.

In an exemplary embodiment, the first charging component 20 includes a temperature sensor 32 operably coupled to the charging controller 30 to monitor a temperature of the charging terminals 26. The vehicle charging may be controlled based on the temperature readings of the temperature sensor 32. The temperature sensor 32 may be used for arc detection, such as by monitoring for a spike in temperature or a temperature above a threshold temperature, which may be higher than a normal operating temperature range. The temperature sensor assembly (including the cables) can act as an antenna and detect EMI from the arc and thus operate as an arc sensor.

In an exemplary embodiment, the first charging component 20 includes an arc sensor assembly 34 operably coupled to the charging controller 30 to monitor for arc signatures from an arc event transmitted along the power transmission lines within the first charging component 20, such as at the charging terminal 26 and/or along the power conductors 28. The arc sensor assembly 34 is operably coupled to the charging controller 30 to control the vehicle charging, such as based on detected arc signals. For example, when the arc event is detected, the charging controller 30 may immediately shut off the power supply to stop the charging process and extinguish the arc. The charging controller 30 may communicate with the second charging component 40, such as to shut off the power supply to stop the charging process.

In an exemplary embodiment, the arc sensor assembly 34 includes a diversity antenna 36 to improve identification of arc events and control the charging operation. The charging controller 30 is operated based on signals from the diversity antenna 36. The diversity antenna 36 provides at least one of positional diversity, radiation pattern diversity, polarization diversity, frequency diversity, and mode diversity for identification of arc events and improved control of the charging operation.

In an exemplary embodiment, the arc sensor assembly 34 is able to identify false positive arc events. For example, the diversity antenna 36 is used to differentiate arc signatures to identify false positive arc events to control the charging operation, such as to maintain the charging process if the arc event is identified as a false positive. In an exemplary embodiment, the arc sensor assembly 34 is able to differentiate between arc signals on the power transmission lines that are generated by the vehicle and arc signals or noise generated from external sources, such as sources other than the vehicle charging system. By differentiating between signals generated by the vehicle charging system and signals generated from other sources (for example, noise), the vehicle charging may be properly controlled for improved operation of the vehicle charging system.

In an exemplary embodiment, the diversity antenna 36 includes one or more diversity antenna elements 38. The diversity antenna elements 38 provide the positional diversity and/or the radiation pattern diversity and/or the polarization diversity and/or the frequency diversity and/or the mode diversity for proper monitoring of the vehicle charging signals and identification of the arc events to control the charging operation. One or more of the diversity antenna elements 38 may be located proximate to the power transmission line(s) for monitoring the electromagnetic fields of the signals along the power transmission lines. One or more of the diversity antenna elements 38 may be located remote from the power transmission lines within the vehicle for monitoring for external signals (for example, noise), which can be used to discriminate vehicle charging signals from external signals transmitted along the power transmission lines. In an exemplary embodiment, the diversity antenna elements 38 may include e-field antenna elements and/or h-field antenna elements and/or b-field antenna elements. The antenna elements 38 may measure electrostatic signals. The antenna elements 38 may measure magnetic signals. Other types of antenna elements may be used in alternative embodiments. In an exemplary embodiment, the diversity antenna elements 38 may include omnidirectional antenna elements and/or directional antenna elements. The directional antenna elements may face in the direction of the power transmission lines to receive the electromagnetic fields from the power transmission lines, whereas the omnidirectional antenna elements may receive signals from not only the power transmission lines but also from external sources to help discriminate the signals. The different diversity antenna elements 38 may detect signals in different frequency ranges. The arc sensor assembly 34 may include processing devices, such as a noise blanker, one or more receivers, a digital signal processor, a beam steering device, a diversity switching device, a neural network, frequency diplexers, and the like, to process the signals.

The arc sensor assembly 34 (and/or components of the arc sensor assembly 34) may be provided at various locations within the vehicle charging system 10. For example, the arc sensor assembly 34 may be located in or on the first charging component 20. In other various embodiments, the arc sensor assembly 34 may be located in or on the vehicle 14, such as in or on the battery system 12. For example, the arc sensor assembly 34 may be incorporated in a battery distribution unit (BDU) or other component of the battery system 12.

The second charging component 40 includes a housing 44 holding a plurality of charging terminals 46 and power conductors 48 coupled to the charging terminals 26. The charging terminals 46 are configured to be mated with the charging terminals 26. In various embodiments, the charging terminals 46 are socket terminals and the charging terminals 26 are pin terminals; however, other types of terminals may be used in alternative embodiments. The charging terminals 46 may be DC charging terminals and or AC charging terminals. The power conductors 48 may be power cables, busbars, or other types of conductors.

The second charging component 40 includes a charging controller 50, which may be used to control vehicle charging. For example, the charging controller 50 may control power supply along the charging terminals 46. The charging controller 50 may communicate with the first charging component 20. The charging controller 50 may turn on the power supply, turn off the power supply, increase the power supply, and/or decrease the power supply. The charging controller 50 may control the voltage and/or current supplied by the second charging component 40.

In an exemplary embodiment, the second charging component 40 includes a temperature sensor 52 operably coupled to the charging controller 50 to monitor a temperature of the charging terminals 46. The vehicle charging may be controlled based on the temperature readings of the temperature sensor 52. The temperature sensor 52 may be used for arc detection, such as by monitoring for a spike in temperature or a temperature above a threshold temperature, which may be higher than a normal operating temperature range. The temperature sensor assembly (including the cables) can act as an antenna and detect EMI from the arc and thus operate as an arc sensor.

In an exemplary embodiment, the second charging component 40 includes an arc sensor assembly 54 operably coupled to the charging controller 50 to monitor for arc signatures from an arc event transmitted along the power transmission lines within the second charging component 40, such as at the charging terminal 46 and/or along the power conductors 48. The arc sensor assembly 54 is operably coupled to the charging controller 50 to control the vehicle charging, such as based on detected arc signals. For example, when the arc event is detected, the charging controller 50 may immediately shut off the power supply to stop the charging process and extinguish the arc. The charging controller 50 may communicate with the first charging component 20, such as to shut off the power supply to stop the charging process.

In an exemplary embodiment, the arc sensor assembly 54 includes a diversity antenna 56 to improve identification of arc events and control the charging operation. The charging controller 50 is operated based on signals from the diversity antenna 56. The diversity antenna 56 provides at least one of positional diversity, radiation pattern diversity, polarization diversity, frequency diversity, and mode diversity for identification of arc events and improved control of the charging operation.

In an exemplary embodiment, the arc sensor assembly 54 is able to identify false positive arc events. For example, the diversity antenna 56 is used to differentiate arc signatures to identify false positive arc events to control the charging operation, such as to maintain the charging process if the arc event is identified as a false positive. In an exemplary embodiment, the arc sensor assembly 54 is able to differentiate between arc signals on the power transmission lines that are generated by the power supply and arc signals or noise generated from external sources, such as sources other than the charging system. By differentiating between signals generated by the charging system and signals generated from other sources (for example, noise), the vehicle charging may be properly controlled for improved operation of the charging system.

In an exemplary embodiment, the diversity antenna 56 includes one or more diversity antenna elements 58. The diversity antenna elements 58 provide the positional diversity and/or the radiation pattern diversity and/or the polarization diversity and/or the frequency diversity and/or the mode diversity for proper monitoring of the vehicle charging signals and identification of the arc events to control the charging operation. One or more of the diversity antenna elements 58 may be located proximate to the power transmission line(s) for monitoring the electromagnetic fields of the signals along the power transmission lines. One or more of the diversity antenna elements 58 may be located remote from the power transmission lines, such as within the charging station, for monitoring for external signals (for example, noise), which can be used to discriminate vehicle charging signals from external signals transmitted along the power transmission lines. In an exemplary embodiment, the diversity antenna elements 58 may include e-field antenna elements and/or h-field antenna elements and/or b-field antenna elements. The antenna elements 58 may measure electrostatic signals. The antenna elements 58 may measure magnetic signals. Other types of antenna elements may be used in alternative embodiments. In an exemplary embodiment, the diversity antenna elements 58 may include omnidirectional antenna elements and/or directional antenna elements. The directional antenna elements may face in the direction of the power transmission lines to receive the electromagnetic fields from the power transmission lines, whereas the omnidirectional antenna elements may receive signals from not only the power transmission lines but also from external sources to help discriminate the signals. The different diversity antenna elements 58 may detect signals in different frequency ranges. The arc sensor assembly 54 may include processing devices, such as a noise blanker, one or more receivers, a digital signal processor, a beam steering device, a diversity switching device, a neural network, frequency diplexers, and the like, to process the signals.

The arc sensor assembly 54 (and/or components of the arc sensor assembly 54) may be provided at various locations within the vehicle charging system 10. For example, the arc sensor assembly 54 may be located in or on the charging plug. In other various embodiments, the arc sensor assembly 54 may be located in or on the charging station.

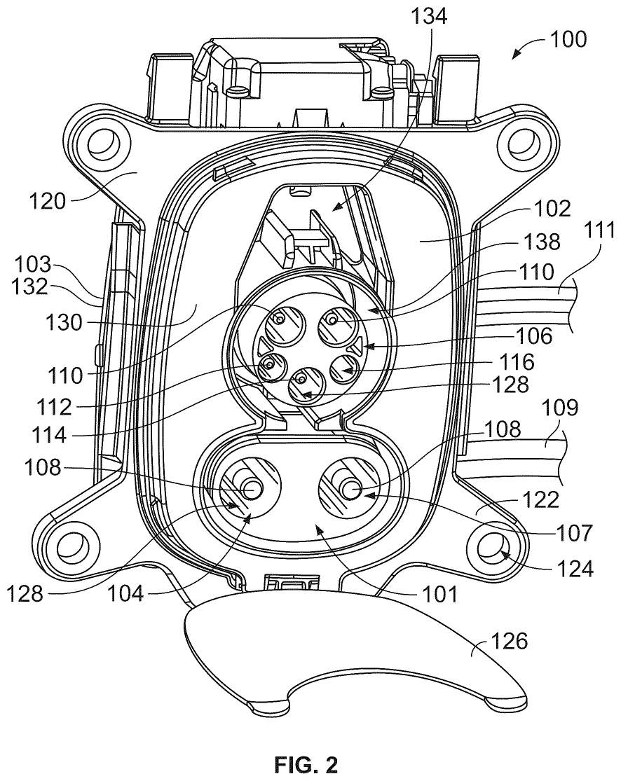

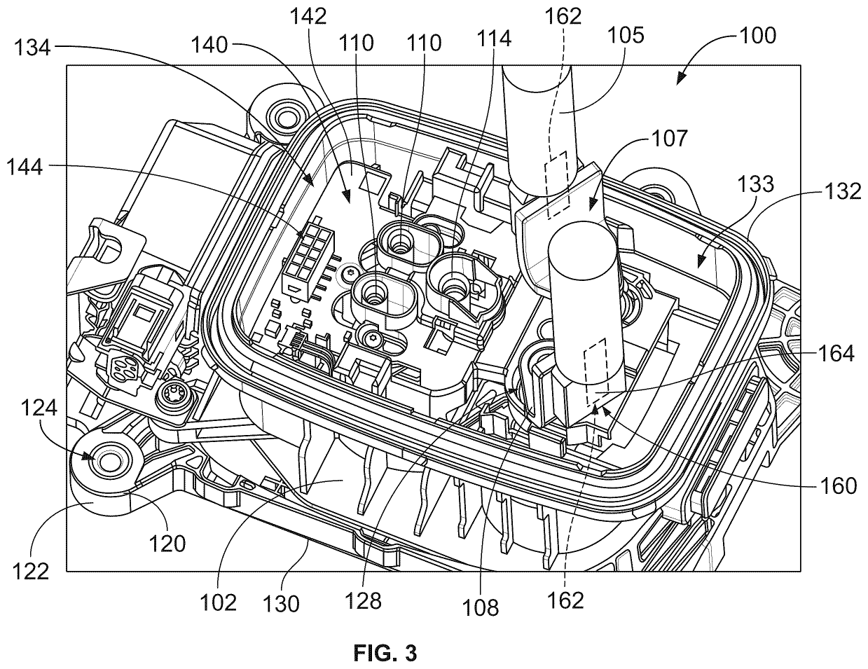

FIG. 2 is a front perspective view of a charging component 100 in accordance with an exemplary embodiment. FIG. 3 is a rear perspective view of the charging component 100 in accordance with an exemplary embodiment. In the illustrated embodiment, the charging component 100 is a charging inlet assembly and may be referred to hereinafter as a charging inlet assembly 100. The charging inlet assembly 100 is configured to be mated with a complimentary charging component (not shown), such as a charging connector or plug charger.

The charging inlet assembly 100 defines a power connector 101 configured to be electrically connected to the charging connector for charging a battery system of a vehicle, such as an electric vehicle (EV) or hybrid electric vehicle (HEV). In an exemplary embodiment, the charging inlet assembly 100 is configured for mating with a DC fast charging connector, such as the SAE combo CCS charging connector or the NACS charging connector, in addition to AC charging connectors, such as the SAE J1772 charging connector. In various embodiments, the charging inlet assembly 100 has a CCS1 (5 pin) AC configuration. In other various embodiments, the charging inlet assembly 100 may have a CCS2 (7 pin) AC configuration. Other standard inlet configurations may be used in alternative embodiments, such as the NACS configuration.

The charging inlet assembly 100 includes a housing 102 configured to be mounted in the vehicle. The housing 102 forms a portion of the power connector 101 for mating with the charging connector. A rear cover 103 (shown in FIG. 2 but removed in FIG. 3 to illustrate components of the charging inlet assembly 100) is coupled to a rear of the housing 102 to close out the housing 102 and the internal components of the charging inlet assembly 100. The rear cover 103 may be sealed to the housing 102 to prevent moisture and debris from entering the internal compartment of the housing 102. In an exemplary embodiment, the power connector 101 defines a DC charging portion 104 and an AC charging portion 106. The charging portions 104, 106 may form receptacles or openings that receive a plug of the charging connector. The charging inlet assembly 100 includes a plurality of charging terminals 107 for connection to the charging connector. Power conductors 105 are electrically connected to the charging terminals 107 and routed within the vehicle, such as to the battery. The power conductors 105 may be power cables, busbars, or other types of conductors. The charging terminals 107 and the power conductors 105 form power transmission lines through the vehicle.

The DC charging portion 104 is configured for mating with a DC charging connector or a DC section of the charging connector. The DC charging portion may be used for fast charging. In an exemplary embodiment, the charging terminals 107 of the charging inlet assembly 100 include DC charging terminals 108 at the DC charging portion 104, such as a pair of the DC charging terminals 108. The DC charging terminals 108 are configured to be electrically connected to the DC charging connector. The charging inlet assembly 100 includes DC power conductors 109 (FIG. 2) electrically connected to the DC charging terminals 108. The DC power conductors 109 may be terminated directly to the DC charging terminals 108, such as being crimped or welded to the DC charging terminals 108. In other embodiments, the DC power conductors 109 may be electrically connected to the DC charging terminals 108 through a separable interface, such as through connectors mated to the housing 102 at the rear. The DC charging terminals 108 and the DC power conductors 109 form power transmission lines through the vehicle.

The AC charging portion 106 is configured for mating with an AC charging connector or an AC section of the charging connector. In an exemplary embodiment, the charging terminals 107 of the charging inlet assembly 100 includes AC power terminals 110 at the AC charging portion 106, such as a pair of the AC power terminals 110. The charging terminals 107 of the charging inlet assembly 100 include a proximity terminal 112 at the AC charging portion 106. The charging terminals 107 of the charging inlet assembly 100 include a ground terminal 114 at the AC charging portion 106. The charging terminals 107 of the charging inlet assembly 100 include a communication terminal 116 at the AC charging portion 106. The AC power terminals 110, the proximity terminal 112, the ground terminal 114, and the communication terminal 116 are configured to be electrically connected to the AC charging connector.

The charging inlet assembly 100 includes AC conductors 111 (FIG. 2) electrically connected to the corresponding AC terminals 110, 112, 114, 116. The AC conductors 111 may be terminated directly to the AC terminals 110, 112, 114, 116, such as being crimped or welded thereto. In other embodiments, the AC conductors 111 may be electrically connected to the AC terminals 110, 112, 114, 116 through a separable interface, such as through connectors mated to the housing 102 at the rear. The AC charging terminals 110 and the AC power conductors 111 form power transmission lines through the vehicle.

The conductors 109, 111 extend from the charging inlet assembly 100 to another component of the vehicle, such as the battery system of the vehicle. The conductors 109, 111 transmit power, such as to the battery of the vehicle. The DC power conductors 109 may transmit high voltage for charging the battery and the AC conductors 111 may transmit low voltage for charging the battery. Optionally, one or more of the conductors 111 may be electrically connected to a battery control unit (not shown) of the battery system, such as to transmit data between the charging inlet assembly 100 and the battery system, such as data relating to the charging operation. For example, the conductor 111 may transmit data relating to charging start/stop, operating temperature of the power terminals 108 and/or 110, or other charging data. The conductor 111 may send a proximity signal to the battery system indicating when the charging device is mated to the power connector 101 of the charging inlet assembly 100.

The charging inlet assembly 100 includes a mounting flange 120 (FIG. 1) coupled to the housing 102. The mounting flange 120 is used to couple the charging inlet assembly 100 to the vehicle. The mounting flange 120 includes mounting tabs 122 having openings 124 that receive fasteners (not shown) used to secure the charging inlet assembly 100 to the vehicle. Other types of mounting features may be used to secure the charging inlet assembly 100 to the vehicle. The mounting flange 120 may include a seal to seal the charging inlet assembly 100 to the vehicle.

In an exemplary embodiment, the charging inlet assembly 100 includes a terminal cover 126 (FIG. 2) at a front 130 of the housing 102. The terminal cover 126 is hingedly coupled to the mounting flange 120 and/or the housing 102. The terminal cover 126 is used to cover portions of the housing 102, such as the power connector 101. The terminal cover 126 may be used to cover the DC charging terminals 108 and/or the AC power terminals 110, which are located in corresponding terminal channels 128 in the housing 102.

The rear cover 103 is provided at a rear 132 of the housing 102 to close access to a rear chamber 133 at the rear 132 of the housing 102. The rear cover 103 may be clipped or latched onto the main part of the housing 102, such as using clips or latches. Other types of securing features, such as fasteners may be used in alternative embodiments. A perimeter seal may be provided between the rear cover 103 and the housing 102.

In an exemplary embodiment, the housing 102 of the charging inlet assembly 100 includes an internal cavity 134 that receives the components of the charging inlet assembly 100. The rear chamber 133 is at the rear of the internal cavity 134. The internal cavity 134 includes the terminal channels 128 that receive the corresponding charging terminals 107. The terminal channels 128 may be separated from each other and other components by walls of the housing 102. The internal cavity 134 includes a front chamber 138 at the front that receives the charging connector.

In an exemplary embodiment, the charging inlet assembly 100 includes a charging controller 140 for controlling charging of the vehicle through the charging inlet assembly 100. The charging controller 140 (or components thereof) may be received in the internal cavity 134, such as in the rear chamber 133. The charging controller 140 may be communicatively coupled to the other charging component, such as the charging connector or plug, to control the charging activity or to another charging controller (for example, within the battery distribution unit) within the vehicle for controlling the charging process. The charging controller 140 may be communicatively coupled to the charging connector through one or more of the terminals 107. The charging controller 140 may turn on the power supply, turn off the power supply, increase the power supply, and/or decrease the power supply. The charging controller 140 may be located remote from the housing 102, such as at the battery control module of the vehicle charging system.

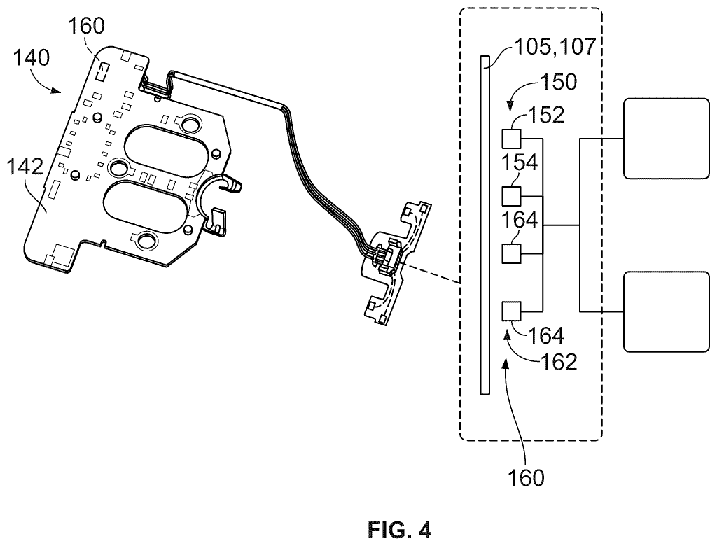

With additional reference to FIG. 4, which is a perspective view of the charging controller 140 in accordance with an exemplary embodiment, the charging controller 140 includes a circuit board 142, a control device 144, and other various components and circuitry to control operation of the charging inlet assembly 100. The control device 144 may be a processor or microcontroller. The control device 144 may include a multi-pin connector coupled to the circuit board 142.

In an exemplary embodiment, the control assembly includes one or more sensors 150 used to control the charging operation. The sensors 150 are used to sense operating characteristics of the components or the charging process to control charging. The sensors 150 are connected to the charging controller 140, such as being connected to the circuit board 142 by a wire or connector.

In various embodiments, the sensors 150 include temperature sensors 152. The temperature sensors 152 monitor operating temperatures of the DC charging terminals 108. The charging operation may be controlled based on the operating temperatures of the DC charging terminals 108. For example, as the temperature increases or approaches an allowable operating temperature, the power supply may be decreased. For example, the voltage or current may be reduced. The charging operation may stop if the operating temperature of the DC charging terminals 108 is above a threshold temperature. The temperature sensor 152 may be used for arc detection, such as by monitoring for a spike in temperature or a temperature above a threshold temperature, which may be higher than a normal operating temperature range.

In various embodiments, the sensors 150 include one or more current sensors 154 monitoring current transmitted along the power transmission lines. A spike in the current or a current above a threshold (for example, above a normal charging level), may indicate an arc event. The charging operation may be controlled based on the sensed current. For example, the charging operation may stop if the arc event is detected. The sensors 150 may include additional systems to help identify false positive arc events and/or to reduce noise, thereby allowing charging to continue if the detected event is a false positive arc event.

Other types of sensors 150 may be provided in alternative embodiments, such as an optical sensor configured to detect arc events. For example, the optical sensor may include a light detector, such as a photodiode. The various types of sensors (temperature, current, optical, antenna, vibration, etc.) provide multi-modal arc detection by monitoring for arc events using different modes of monitoring.

In an exemplary embodiment, the sensors 150 include an arc sensor assembly 160 coupled to the charging controller 140. The arc sensor assembly 160 is configured to be positioned within the vehicle, such as proximate to the power transmission lines, for detecting arc signatures along the power transmission lines from an arc event. The arc sensor assembly 160 transmits an arc output signal to the charging controller 140. The arc output signal may be based on detection of the arc signature.

The arc sensor assembly 160 operably coupled to the charging controller 140 to monitor for arc signatures from an arc event transmitted along the power transmission lines within the first charging component 20, such as at the charging terminal 107 and/or along the power conductors 105. The arc sensor assembly 160 is operably coupled to the charging controller 140 to control the vehicle charging, such as based on detected arc signals. For example, when the arc event is detected, the charging controller 140 may immediately shut off the power supply to stop the charging process and extinguish the arc. The charging controller 140 may communicate with the second charging component 40, such as to shut off the power supply to stop the charging process.

In an exemplary embodiment, the arc sensor assembly 160 includes a diversity antenna 162 to improve identification of arc events and control the charging operation. The charging controller 140 is operated based on signals from the diversity antenna 162. The diversity antenna 162 provides at least one of positional diversity, radiation pattern diversity, polarization diversity, frequency diversity, and mode diversity for identification of arc events and improved control of the charging operation. The arc sensor assembly 160 may include processing devices, such as a noise blanker, one or more receivers, a digital signal processor, a beam steering device, a diversity switching device, a neural network, frequency diplexers, and the like, to process the signals.

In an exemplary embodiment, the arc sensor assembly 160 is able to identify false positive arc events. For example, the diversity antenna 162 is used to differentiate arc signatures to identify false positive arc events to control the charging operation, such as to maintain the charging process if the arc event is identified as a false positive. In an exemplary embodiment, the arc sensor assembly 160 is able to differentiate between arc signals on the power transmission lines that are generated by the vehicle and arc signals or noise generated from external sources, such as sources other than the vehicle charging system. By differentiating between signals generated by the vehicle charging system and signals generated from other sources (for example, noise), the vehicle charging may be properly controlled for improved operation of the vehicle charging system.

In an exemplary embodiment, the diversity antenna 162 includes one or more diversity antenna elements 164. The diversity antenna elements 164 are capable of detecting signals around the vehicle, such as along the power transmission lines. The diversity antenna 162 may include one or more antenna circuits operably coupled to the diversity antenna elements 164 and other components for transmitting signals from the diversity antenna 162. The antenna circuits may include or be connected to processing devices, such as a digital signal processor, a neural network, frequency diplexers, and the like, to process the signals.

In an exemplary embodiment, the diversity antenna elements 164 provide the positional diversity and/or the radiation pattern diversity and/or the polarization diversity and/or the frequency diversity and/or the mode diversity for proper monitoring of the vehicle charging signals and identification of the arc events to control the charging operation.

One or more of the diversity antenna elements 164 may be located proximate to the power transmission line(s) for monitoring the electromagnetic fields of the signals along the power transmission lines. One or more of the diversity antenna elements 164 may be located remote from the power transmission lines within the vehicle for monitoring for external signals (for example, noise), which can be used to discriminate vehicle charging signals from external signals transmitted along the power transmission lines.

In an exemplary embodiment, the diversity antenna elements 164 may include e-field antenna elements and/or h-field antenna elements and/or b-field antenna elements. The antenna elements 164 may measure electrostatic signals. The antenna elements 164 may measure magnetic signals. Other types of antenna elements may be used in alternative embodiments. In an exemplary embodiment, the diversity antenna elements 164 may include omnidirectional antenna elements and/or directional antenna elements. The directional antenna elements may face in the direction of the power transmission lines to receive the electromagnetic fields from the power transmission lines, whereas the omnidirectional antenna elements may receive signals from not only the power transmission lines but also from external sources to help discriminate the signals. The different diversity antenna elements 164 may detect signals in different frequency ranges.

In an exemplary embodiment, the arc sensor assembly 160 may determine magnitudes of arc signals on the power transmission lines and may determine phases of the arc signals on the power transmission lines. The arc sensor assembly 160 may identify common mode signals and differential mode signals to discriminate between the vehicle charging signals from the vehicle being monitored that are transmitted along the power transmission lines from external signals generated from sources other than the vehicle charging system of the vehicle being monitored. In the differential mode, the signals on the power transmission lines may be equal in magnitude but opposite in phase and thus would essentially cancel out, indicating that the detected signals are vehicle charging signals. However, in the common mode, because the signals are produced from a different source (for example, an arc event at a nearby vehicle charging at a different charging station), the signals would be received by both power transmission lines and would be equal in magnitude and in the same phase, indicating that the signals are generated from an external source thus identifying a false positive arc event. Discrimination between the common mode and the differential mode allows the system to accurately distinguish between an arc event and a false positive arc event.

The arc sensor assembly 160 (and/or components of the arc sensor assembly 160) may be provided at various locations within the vehicle charging system 10. For example, the arc sensor assembly 160 may be located in or on the charging inlet assembly 100. In other various embodiments, the arc sensor assembly 160 may be located in or on the vehicle, such as in or on the battery system. For example, the arc sensor assembly 160 may be incorporated in a battery distribution unit (BDU) or other component of the battery system.

In various embodiments, the arc sensor assembly 160 is incorporated into the charging controller 140, such as being incorporated into the circuit board 142. In other various embodiments, the arc sensor assembly 160 may be located remote from the charging controller and coupled thereto either by a wired or wireless connection. The signals from the arc sensor assembly 160 may be processed, such as by low noise amplification and/or filtering along the signal paths. The various types of connection may allow increased flexibility of the location of the detector circuitry compared to the antenna elements. The arc sensor assembly 160 may be located within the housing 102, such as in the internal cavity 134. As such, the arc sensor assembly 160 may be located proximate to the charging terminals 107 and/or the ends of the power conductors 105. In other various embodiments, the arc sensor assembly 160 may be located remote from the housing 102, such as along the power conductors 105 outside of the housing 102 or in the battery assembly, such as in the battery distribution unit (BDU).

The diversity antenna 162 transmits one or more outputs (for example, arc signal output) to the charging controller 140. The charging controller 140 may include processing devices, such as a microcontroller, a processor, a digital signal processor, a neural network, frequency diplexers, and the like, to process the signals. The charging controller 140 is used to control the charging operation. For example, the charging controller 140 may turn on the power supply, turn off the power supply, increase the power supply, and/or decrease the power supply based on the signals from the antenna elements 164 (for example, based on the current output signal). For example, when the arc event is detected, the charging operation is stopped. The current and voltage from the charging connector is stopped immediately to prevent damage to the components or the vehicle.

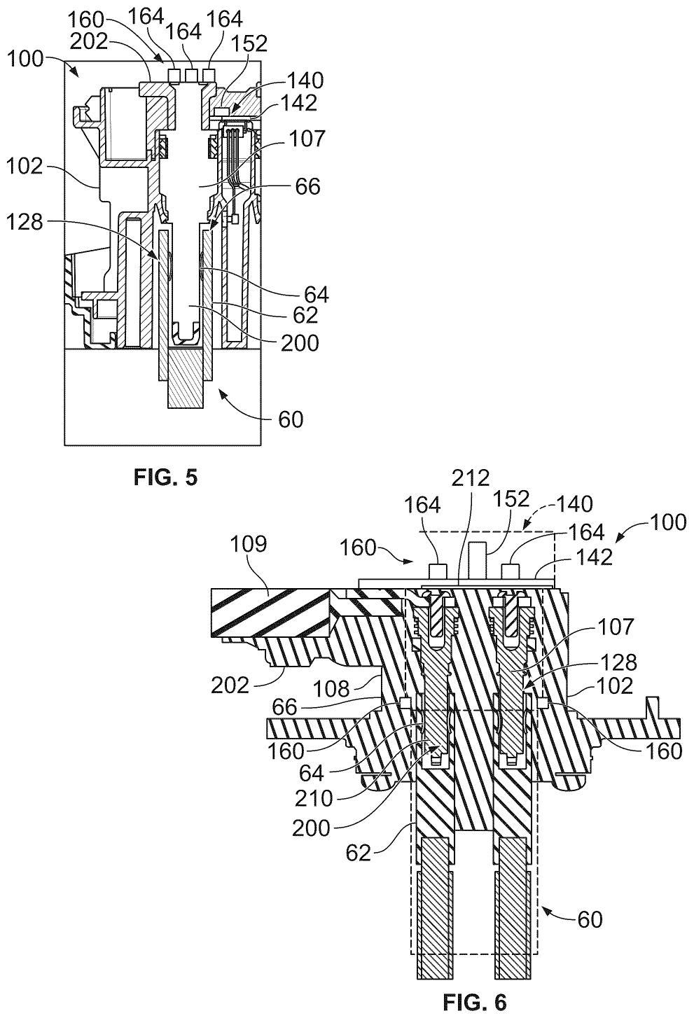

FIG. 5 is a cross-sectional view of the charging component 100 in accordance with an exemplary embodiment showing a second charging component 60 coupled to the charging component. FIG. 6 is a cross sectional view of the charging component 100 in accordance with an exemplary embodiment showing the second charging component 60 coupled to the charging component. In the illustrated embodiment, the charging component 100 is the charging inlet assembly. The second charging component 60 is a charging connector such as a plug charger.

The charging terminals 107 are shown in the terminal channels 128 of the housing 102. The charging terminals 107 are mated with charging terminals 62 of the charging component 60. In the illustrated embodiment, the charging terminals 107 are pin terminals and the charging terminals 62 are socket terminals having spring contacts 64 in the sockets configured to electrically connect the charging terminals 62 and the charging terminals 107. The spring contacts 64 form a compliant, separable interface. The spring contacts 64 may be susceptible to failure due to overheating, and the failure may lead to an electrical arc event. The temperature sensors 152 monitor temperature of the charging terminals 107. The diversity antenna elements 164 monitor the electromagnetic fields, such as radio frequency signals, on the power transmission line for arc events, such as at mating ends 66 of the charging terminals 62 or mating ends of the charging terminals 107.

The charging terminal 107 includes a mating pin 200 at a mating end 210 of the charging terminal 107 and a cable connector 202 at a rear 212 of the charging terminal 107. The charging terminal 107 extends along a longitudinal axis. The mating pin 200 is configured to be mated to the spring contact 64 of the charging terminal 62 of the charging component 60. The cable connector 202 is configured to be electrically connected to the power conductor 109. In various embodiments, the cable connector 202 is configured to be terminated to the power conductor 109 by crimping to the power conductor 109. In other various embodiments, the cable connector 202 is terminated to the power conductor 109 by other processes, such as being welded to a weld tab at the rear end of the charging terminal 107. The conductor 109 may extend from the charging terminal 107 perpendicular to the longitudinal axis. Alternatively, the conductor 109 may extend from the charging terminal 107 parallel to the longitudinal axis.

In an exemplary embodiment, the temperature sensor 152 is coupled to the charging terminal 107 at the rear of the charging terminal 107, such as at the cable connector 202. The charging terminal 107 is both electrically conductive and thermally conductive. As the mating pin 200 heats up during charging, the entire body of the charging terminal 107 similarly heats up. Such increase in temperature is detected by the temperature sensor 152. In various embodiments, the temperature sensor 152 is a thermistor. The temperature sensor 152 may include a resistance temperature detector.

The arc sensor assembly 160 monitors signals around the vehicle, such as vehicle charging signals/arc signals along the power transmission line that are generated by the vehicle and arc signals or noise generated from external sources, such as sources other than the vehicle charging system. Monitoring the electromagnetic fields allows the arc sensor assembly 160 to detect and identify an arc event occurring within the vehicle being monitored versus an arc event or other noise occurring in another vehicle or from another external source. Monitoring the electromagnetic fields allows the arc sensor assembly 160 to detect false positive arc events occurring external to the power transmission line, such as occurring on a different vehicle at the charging station or other external events that could lead to a spike in RF signals on the power transmission lines. By detecting the arc event, the arc sensor assembly 160 is able to signal to the charging controller 140 to shut down the charging operation to protect the components of the charging inlet assembly 100 and the vehicle.

In various embodiments, the arc sensor assembly 160 monitors for an arc noise signature to detect the arc event. For example, arc noise is generated by the arc event, such as in the radiofrequency range as a consequence of arc energy. The characteristic noise signature of the electrical arcing may be in a predetermined range, such as between 1 kHz-100 GHz. The characteristic noise signature of the electrical arcing may be in a more particular range, such as between 100-500 kHz. The arc sensor assembly 160 detects the stochastic energy, or noise signature, generated by the electrical arc. In an exemplary embodiment, the arc sensor assembly 160 may monitor the power transmission line of the charging inlet assembly 100 to detect the arc noise signature on the power transmission line corresponding to the arc event. The arc sensor assembly 160 may monitor the current along the charging terminals 107 and/or the power conductors 109.

In various embodiments, the charging controller 140 may include an arc fault circuit interrupter (AFCI) device to protect against electrical arcing, such as to shut down the charging circuit when an arc is detected. The diversity antenna elements 164 monitors for the arc noise signature on the electrical circuit to detect the arc noise signature conducted on the power transmission line when the arc fault occurs. The charging controller 140 may include an internal processor in the ACFI device that distinguishes between normal operation and the hazardous arcing and will automatically open the circuit to reduce the risk of damage to the system.

In various embodiments, the arc sensor assembly 160 is connected to other wiring or circuits to detect the arc noise signature. The arc sensor assembly 160 may be located at the battery, such as at the battery distribution unit (BDU) rather than at the charging inlet housing. In other various embodiments, the arc sensor assembly 160 includes a separate, dedicated arc detection wire, which may be routed from the charging terminal 107 to the circuit board 142 or routed to another component, such as the battery control module. The arc sensor assembly 160 may include a resistor-capacitor-inductor network or filter at the charging terminal 107 or at the circuit board 142 to enhance sensitivity to arc signature and minimize sensitivity to normal vehicle electrical noise.

In an exemplary embodiment, the diversity antenna elements 164 are electrically coupled to the power transmission line at or near the cable connector 202 at the rear 212 of the charging terminal 107. The diversity antenna elements 164 may be coupled to the cable connector 202 or to the conductor 109. In various embodiments, the diversity antenna elements 164 may be located between two different power lines to measure signals from both power transmission lines. In various embodiments, different diversity antenna elements 164 may be provided for each of the power transmission lines to monitor the respective power transmission lines to monitor the electrical signature along such power transmission lines. The diversity antenna elements 164 may be located at other locations within the vehicle, such as remote from the power transmission lines (for example, front bumper, roof of the vehicle, trunk, and the like). The arc sensor assembly 160 may compare the signals from the different diversity antenna elements 164 to determine if an arc event is occurring and/or to determine if a false positive arc event is occurring.

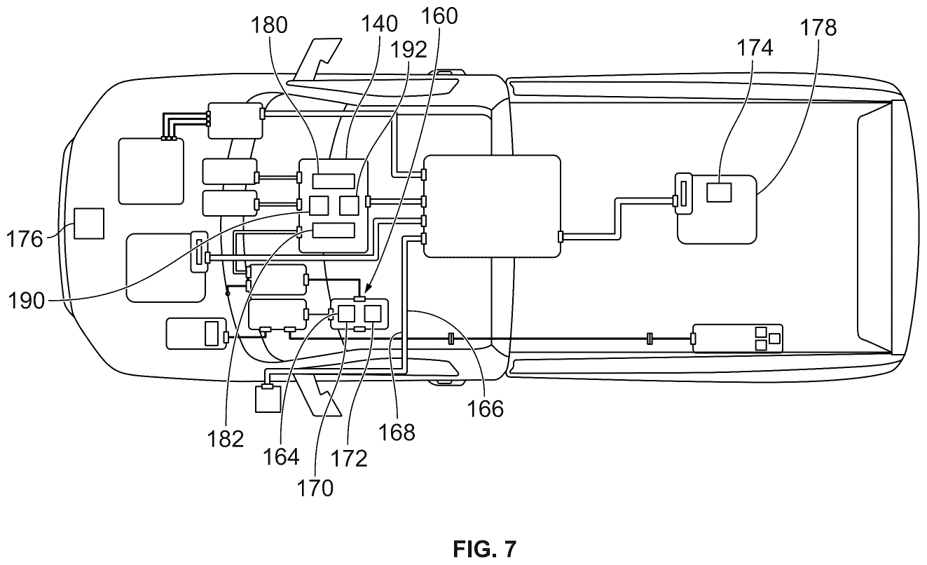

FIG. 7 is a schematic view of the vehicle charging system for the vehicle in accordance with an exemplary embodiment. The arc sensor assembly 160 is coupled to the charging controller 140. The diversity antenna 162 detects signals, such as charging signatures, arc signatures, and noise, in and around the vehicle, such as along the power transmission lines 166, 168. The diversity antenna 162 transmits output signals to the charging controller 140 to control the charging operation. For example, the diversity antenna 162 may transmit charging output signals indicative of the charging operation to the charging controller 140. The diversity antenna 162 may transmit the arc output signal to the charging controller 140 based on detection of the arc signature.

In an exemplary embodiment, the diversity antenna 162 includes a plurality of the diversity antenna elements 164. For example, in the illustrated embodiment, the diversity antenna 162 includes a first diversity antenna element 170, a second diversity antenna element 172, a third diversity antenna element 174, and a fourth diversity antenna 176. The diversity antenna 162 may include greater or fewer diversity antenna elements 164 in alternative embodiments. The diversity antenna elements 170,172, 174, 176 provide at least one of positional diversity, radiation pattern diversity, polarization diversity, frequency diversity, and mode diversity.

In the illustrated embodiment, the first and second diversity antenna elements 170, 172 are located proximate to the power transmission lines 166, 168. The first and second diversity antenna elements 170, 172 are located proximate to each other. In an exemplary embodiment, the first and second diversity antenna elements 170, 172 operate in different reception modes to provide diversity signaling. For example, the first diversity antenna element 170 includes a patch antenna element operating in an e-field reception mode and the second diversity antenna element 172 includes a coil antenna element operating in an h-field reception mode. The first and second diversity antenna elements 170, 172 provide coincident reception of signals to improve confidence in a positive arcing indication. For example, close-in noise has strong e-field and h-field components, whereas distant noise has mainly e-field components. Using both of the diversity antenna elements 170, 172 having different reception modes with coincidence detection avoids producing a false positive result by reducing the possibility of triggering arc detection on more distant external noise signals (for example, from adjacent vehicles at a bank of charging stations, nearby arc welding, spark plug noise from internal combustion engines, or other similar sources).

In other various embodiments, rather than using two diversity antenna elements that use different reception modes, the first and second diversity antenna elements 170, 172 may be different types of antennas having different directional capabilities. For example, the first diversity antenna element 170 may be an omni-directional antenna and the second diversity antenna element 172 may be a directional antenna element. The directional antenna element may be directed to face the power transmission lines 166, 168 to directionally receive signals from the power transmission lines 166, 168 and ignore or block signals from other directions. The omni-directional antenna element may receive signals from all directions to pick up on both the signals from the power transmission lines 166, 168 as well as noise from other external sources. Comparing the signals from the two different types of antennas avoids producing a false positive result by reducing the possibility of triggering arc detection on external noise signals from directions other than the direction of the power transmission lines 166, 168.

In an exemplary embodiment, the third and fourth diversity antenna elements 174, 176 are located in the vehicle remote from the power transmission lines 166, 168, which is in contrast to the first and second diversity antenna elements 170, 172, which are located in the vehicle in close proximity to the power transmission lines 166, 168. The first and second diversity antenna elements 170, 172 are more closely or strongly coupled to the power transmission lines 166, 168 to more acutely identify the signals from the power transmission lines 166, 168, in comparison to the third and fourth diversity antenna elements 174, 176. The third and fourth diversity antenna elements 174, 176 are capable of picking up the external signals. The diversity antenna 162 is capable of desensitizing the vehicle charging system based on the external signals picked up by the third and fourth diversity antenna elements 174, 176. For example, the diversity antenna 162 may blank or cancel out the external signals picked up by the third and fourth diversity antenna elements 174, 176 that are also sensed by the first and second diversity antenna elements 170, 172.

In an exemplary embodiment, the arc sensor assembly 160 includes a noise blanker 180 and one or more receivers 182. The receiver(s) 182 is configured to receive signals from one or more of the diversity antenna elements 164. The signals may be processed by the receiver or transmitted from the receiver to another component for processing. The noise blanker 180 is configured to block certain signals received by the diversity antenna 162, such as signals from external sources, from the receiver 182. The noise blanker 180 improves the operation of the diversity antenna 162 by blocking signals that are unrelated to the vehicle charging operation of the vehicle being monitored (for example, from external sources). For example, the noise blanker 180 is configured to block the signals received by the diversity antenna 162 when an external triggering event is detected from a source other than the vehicle charging system. In an example, the external signals sensed by the third and fourth diversity antenna elements 174, 176 may be used by the noise blanker 180 to block such related signals at the receiver associated with the first and second diversity antenna elements 170, 172. The noise blanker 180 is configured to mitigate the negative effect of noise on the arc detection system. For example, the noise blanker 180 may isolate the receiver 182 from the external noise for a duration or period of time when the external noise is detected so the noise is not presented to the receiver 182 or the effect of the noise is mitigated to improve signal throughput. Signal to noise ratio is improved because the silent (blanked) periods are less different in amplitude from the desired signal than are noise pulses.

In an exemplary embodiment, the third diversity antenna element 174 is located in proximity to a motor inverter 178 of the vehicle to detect switching transients caused by the inverter operation. The noise blanker 180 is configured to block signals at the receiver 182 based on the switching transients detected by the third diversity antenna element.

In an exemplary embodiment, the arc sensor assembly 160 includes a signal processing device 190 processing signals from the diversity antenna 162. The signal processing device 190 includes a beam steering device 192. The beam steering device 192 is configured for beam steering detection to determine direction of arrival of signals at the diversity antenna 162. The beam steering device 192 is configured to determine if the signals directional originate from the power transmission lines 166, 168 or from an external source. In an exemplary embodiment, the signal processing device 190 is configured for diversity switching to select the diversity antenna element 164 from the plurality of diversity antenna elements 164 having the least noise. The receiver 182 may receive and process the signal from the diversity antenna element 164 having the least noise. In an exemplary embodiment, the signal processing device 190 is configured for phase coherent summing and analysis of signals from the diversity antenna in different combinations.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112(f), unless and until such claim limitations expressly use the phrase “means for” followed by a statement of function void of further structure.

What is claimed is:

1. A vehicle charging system for an electric vehicle comprising:
a housing having a mating end for mating with a charging component for the electric vehicle, the housing including an internal cavity;
charging terminals held by the housing in the internal cavity, each charging terminal including a mating end for mating with the charging component, the charging terminals being connected to corresponding power conductors to form power transmission lines;
a charging controller for controlling vehicle charging along the power transmission lines; and
an arc sensor assembly coupled to the charging controller, the arc sensor assembly including a diversity antenna for detecting arc signatures along the power transmission lines from an arc event, the diversity antenna transmitting an arc output signal to the charging controller based on detection of the arc signature.

2. The vehicle charging system of claim 1, wherein the diversity antenna includes a first diversity antenna element and a second diversity antenna element, the first and second diversity antenna elements operating in different reception modes.

3. The vehicle charging system of claim 1, wherein the diversity antenna includes a first diversity antenna element and a second diversity antenna element, the first diversity antenna element including a patch antenna element operating in an e-field reception mode, the second diversity antenna element including a coil antenna element operating in an h-field reception mode.

4. The vehicle charging system of claim 1, wherein the diversity antenna provides at least one of positional diversity, radiation pattern diversity, polarization diversity, frequency diversity, and mode diversity.

5. The vehicle charging system of claim 1, wherein the diversity antenna includes a first diversity antenna element and a second diversity antenna element, the first diversity antenna element located in the vehicle in close proximity to the power transmission lines, the second diversity antenna element located in the vehicle remote from the power transmission lines.

6. The vehicle charging system of claim 1, wherein the arc sensor assembly includes a noise blanker configured to block signals received by the diversity antenna.

7. The vehicle charging system of claim 6, wherein the noise blanker is configured to block the signals received by the diversity antenna when an external triggering event is detected from a source other than the vehicle charging system.

8. The vehicle charging system of claim 1, wherein the diversity antenna including a primary diversity antenna element in close proximity to the power transmission lines closely coupled to the power transmission lines to detect electromagnetic fields from vehicle charging signals transmitted along the power transmission lines, the diversity antenna including a secondary diversity antenna element remote from the power transmission lines to detect external electromagnetic fields from external signals generated from sources other than the vehicle charging system, the arc sensor assembly including a receiver receiving signals from the primary diversity antenna element, the arc sensor assembly including a noise blanker configured to block signals at the receiver based on the external signals from the secondary diversity antenna element.

9. The vehicle charging system of claim 8, wherein the secondary diversity antenna element is configured to be located in proximity to a motor inverter of the vehicle to detect switching transients caused by the inverter operation, the noise blanker configured to block signals at the receiver based on the switching transients detected by the secondary diversity antenna element.

10. The vehicle charging system of claim 1, wherein the arc sensor assembly includes a signal processing device processing signals from the diversity antenna, the signal processing device configured for beam steering detection to determine direction of arrival of signals at the diversity antenna.

11. The vehicle charging system of claim 1, wherein the diversity antenna includes a first diversity antenna element and a second diversity antenna element, the arc sensor assembly including a signal processing device processing signals from the first and second diversity antenna elements, the signal processing device configured for diversity switching to select the first or second diversity antenna elements having the least noise.

12. The vehicle charging system of claim 1, wherein the diversity antenna includes a first diversity antenna element and a second diversity antenna element, the first diversity antenna element being an omnidirectional antenna element, the second diversity antenna element being a directional antenna focused in a direction of the power transmission lines.

13. The vehicle charging system of claim 1, wherein the diversity antenna includes greater than two diversity antenna elements.

14. The vehicle charging system of claim 1, wherein the arc sensor assembly includes a signal processing device processing signals from the diversity antenna, the signal processing device configured for phase coherent summing and analysis of signals from the diversity antenna in different combinations.

15. The vehicle charging system of claim 1, wherein the arc sensor assembly monitors the arc signals at at least one of the power conductors and the charging terminals.

16. The vehicle charging system of claim 1, wherein the arc sensor assembly is located in the internal cavity of the housing.

17. The vehicle charging system of claim 1, wherein the arc sensor assembly is located in a battery distribution unit of a battery system of the electric vehicle.

18. The vehicle charging system of claim 1, wherein the charging controller shuts power supplied to the charging terminals when the arc event is detected.

19. The vehicle charging system of claim 1, wherein the housing is a charging connector housing configured to be removably coupled to a charging inlet housing of the charging component of the vehicle, the charging terminals being socket terminals configured to be mated with pin terminals of the charging component to power the vehicle through the pin terminal.

20. The vehicle charging system of claim 1, wherein the housing is a charging inlet housing configured to be mounted to the vehicle and configured to receive a charging connector housing of the charging component, the charging terminals including pins configured to be mated with socket terminals of the charging component to receive power from the charging component.

21. A vehicle charging system for an electric vehicle comprising:
a housing having a mating end for mating with a charging component for the electric vehicle, the housing including an internal cavity;
charging terminals held by the housing in the internal cavity, each charging terminal including a mating end for mating with the charging component, the charging terminals being connected to corresponding power conductors to form power transmission lines;
a charging controller for controlling vehicle charging along the power transmission lines; and
an arc sensor assembly coupled to the charging controller, the arc sensor assembly including a diversity antenna for detecting arc signatures along the power transmission lines from an arc event, the diversity antenna including a primary diversity antenna element sensing first signals and a secondary diversity antenna element sensing second signals, the arc sensor assembly including a receiver receiving signals from at least one of the primary diversity antenna element and the secondary diversity antenna element, the arc sensor assembly including a noise blanker operably coupled to the receiver to control the signals received by the receiver, the arc sensor assembly transmitting an arc output signal to the charging controller based on the signals received by the receiver.

22. The vehicle charging system of claim 21, wherein the primary diversity antenna element is in close proximity to the power transmission lines being closely coupled to the power transmission lines to detect electromagnetic fields from vehicle charging signals transmitted along the power transmission lines, the secondary diversity antenna element being located remote from the power transmission lines to detect external electromagnetic fields from external signals generated from sources other than the vehicle charging system, the noise blanker configured to block signals at the receiver based on the external signals from the secondary diversity antenna element.

23. A charging inlet assembly for an electric vehicle comprising:
a housing extending between a front and a rear, the housing having a chamber at the rear, the housing having a power connector at the front for receiving a charging connector, the power connector including terminal channels between the front and the rear;
charging terminals received in the corresponding terminal channels, each of the charging terminals including a mating pin and a terminating end opposite the mating pin, the mating pin positioned in the corresponding terminal channel for mating with the charging connector, the terminating end positioned in the chamber at the rear of the housing and being connected to a power conductor to form a power transmission line;
a charging controller for controlling vehicle charging along the power transmission lines during a charging operation; and
an arc sensor assembly coupled to the charging controller, the arc sensor assembly including a diversity antenna for detecting arc signatures along the power transmission lines from an arc event, the diversity antenna transmitting an arc output signal to the charging controller based on detection of the arc signature.
